(19) United States
(12) Patent Application Publication
(10) Pub. No.: US 2019/0051828 A1
(43) Pub. Date: Feb. 14, 2019

(54) REMOVING METHOD OF FLEXIBLE DEVICE

(71) Applicant: Chunghwa Picture Tubes, LTD., Taoyuan City (TW)

(72) Inventors: Che-Cheng Kuo, Taipei City (TW); Ji-Yi Chiou, Taichung City (TW); Yen-Yu Huang, Taoyuan City (TW)

(73) Assignee: Chunghwa Picture Tubes, LTD., Taoyuan City (TW)

(21) Appl. No.: 15/710,844

(22) Filed: Sep. 21, 2017

(30) Foreign Application Priority Data
Aug. 11, 2017 (CN) 201710683964.4

(51) Int. Cl. H01L 51/00; H01L 51/56

(52) U.S. Cl. CPC H01L 51/003; H01L 51/56

(57) ABSTRACT

A removing method of a flexible device is provided. The flexible device is formed on a carrier. The removing method of the flexible device includes providing a roller, a non-visible light source, and a photosensitive tape. The non-visible light source is disposed at an axle center of the roller, and the photosensitive tape is fixed on an outer surface of the roller. The removing method of the flexible device further includes enabling the photosensitive tape on the roller to lean against the flexible device and enabling the roller to rotate so as to peel the flexible device off the carrier; and irradiating the photosensitive tape by the non-visible light source and removing the flexible device from the photosensitive tape. As such, technique costs are saved and damages on the flexible device are lowered.

### CROSS-REFERENCE TO RELATED APPLICATION

This application claims the priority benefit of China application serial no. 201710683964.4, filed on Aug. 11, 2017. The entirety of the above-mentioned patent application is hereby incorporated by reference herein and made a part of this specification.

### BACKGROUND OF THE INVENTION

1. Field of the Invention

The invention relates to a removing method. More particularly, the invention relates to a removing method of a flexible device.

2. Description of Related Art

In the applications of consumer electronics, flexible devices having flexible and bendable characteristics have become the focus in future development. Nevertheless, in the manufacturing process of a flexible device, as the flexible device is manufactured on a carrier most of the time, a technical problem regarding the removal of the flexible device from the carrier easily occurs consequently. In the prior art, laser was adopted to separate the flexible device from the carrier; however, it is difficult to prevent laser from influencing the flexible device during the process. Moreover, significant costs are required to perform laser technique, and laser source itself is an expensive supply. A technical mean is therefore required to replace the laser technique.

### SUMMARY OF THE INVENTION

The invention provides a removing method of a flexible device in which costs may be saved and less damage may be made on the flexible device.

In a removing method of a flexible device provided by an embodiment of the invention, the flexible device is formed on a carrier. The removing method of the flexible device includes following steps. Providing a roller, a non-visible light source, and a photosensitive tape. The non-visible light source is disposed at an axle center of the roller, and the photosensitive tape is fixed on an outer surface of the roller. Enabling the photosensitive tape on the roller to lean against the flexible device and enabling the roller to rotate so as to peel the flexible device off the carrier. Irradiating the photosensitive tape by the non-visible light source. Removing the flexible device from the photosensitive tape.

According to an embodiment of the invention, the removing method of the flexible device further includes cutting the flexible device before performing the removing method of the flexible device.

According to an embodiment of the invention, the method of cutting the flexible device includes a laser.

According to an embodiment of the invention, an adhesion between the carrier and the flexible device may be less than and equal to 0.196 N/cm.

According to an embodiment of the invention, an adhesion between the photosensitive tape and the flexible device may be greater than 1 N/cm before performing the irradiation.

According to an embodiment of the invention, an adhesion between the photosensitive tape and the flexible device may be less than 0.1 N/cm after performing the irradiation.

According to an embodiment of the invention, the roller may be a material pervious to non-visible light.

According to an embodiment of the invention, an intensity of the non-visible light source may range between 800 mJ/cm² plus or minus 10%.

According to an embodiment of the invention, a distance between the non-visible light source and the flexible device may be 100 mm.

According to an embodiment of the invention, the non-visible light source may include an ultraviolet light source.

Based on the above, according to the removing method of the flexible device provided by the embodiments of the invention, after the flexible device is peeled off from the carrier by the roller with the photosensitive tape fixed onto the outer surface, as the adhesion between the photosensitive tape and the flexible device may be changed through the non-visible light source; thereby, the flexible device may be easily removed from the photosensitive tape without the use of laser. In the entire process of the removing method of the flexible device, damages made by laser on the flexible device are therefore prevented, and equipment costs and supply costs are effectively lowered.

To make the aforementioned and other features and advantages of the invention more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1D are schematic flow charts of a removing method of a flexible device according to an embodiment of the invention.

FIG. 2A to FIG. 2D are schematic flow charts respectively corresponding to the removing method of the flexible device of FIG. 1A to FIG. 1D shown in a direction x.

FIG. 3A to FIG. 3B are schematic views of a manufacturing process of a flexible device according to an embodiment of the invention.

### DESCRIPTION OF THE EMBODIMENTS

Descriptions of the invention are given with reference to the exemplary embodiments illustrated by the accompanying drawings. Wherever possible, the same reference numbers are used in the drawings and the description to refer to the same or like parts.

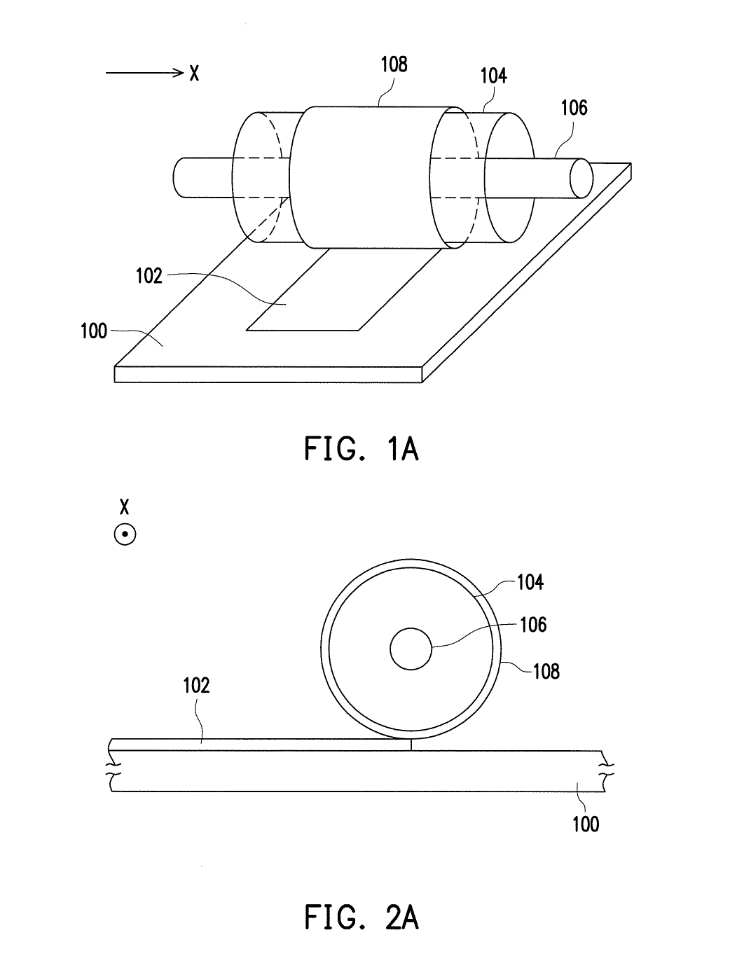

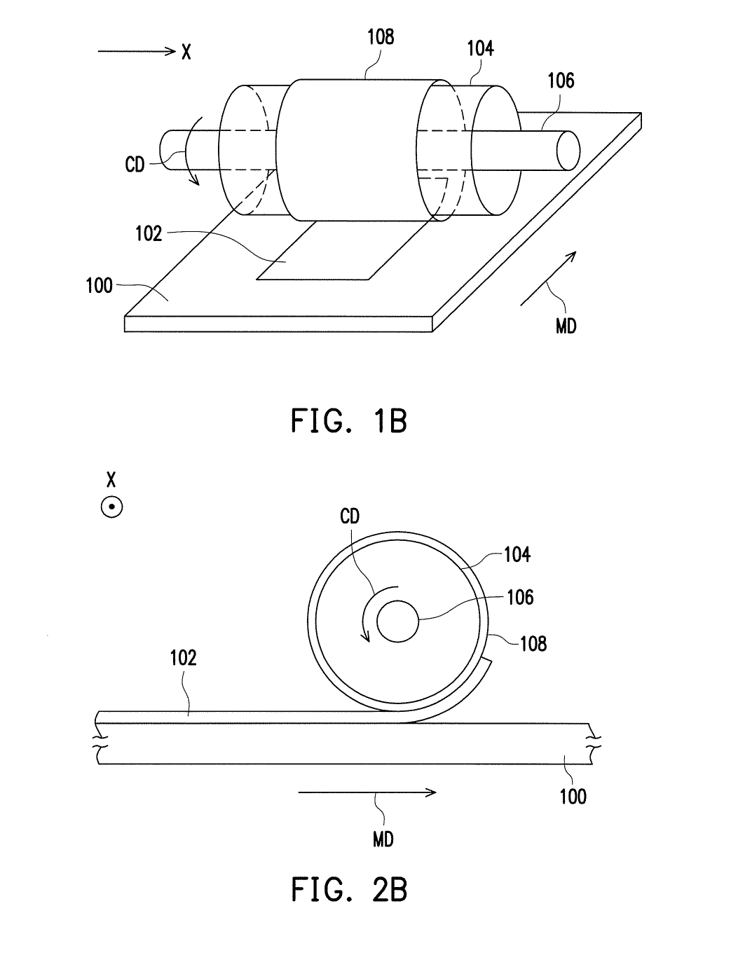

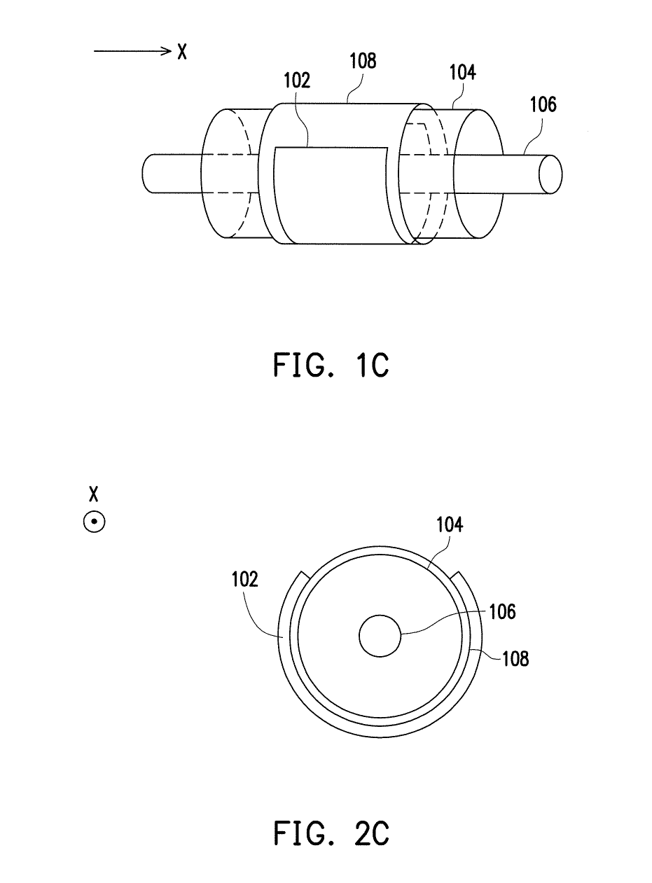

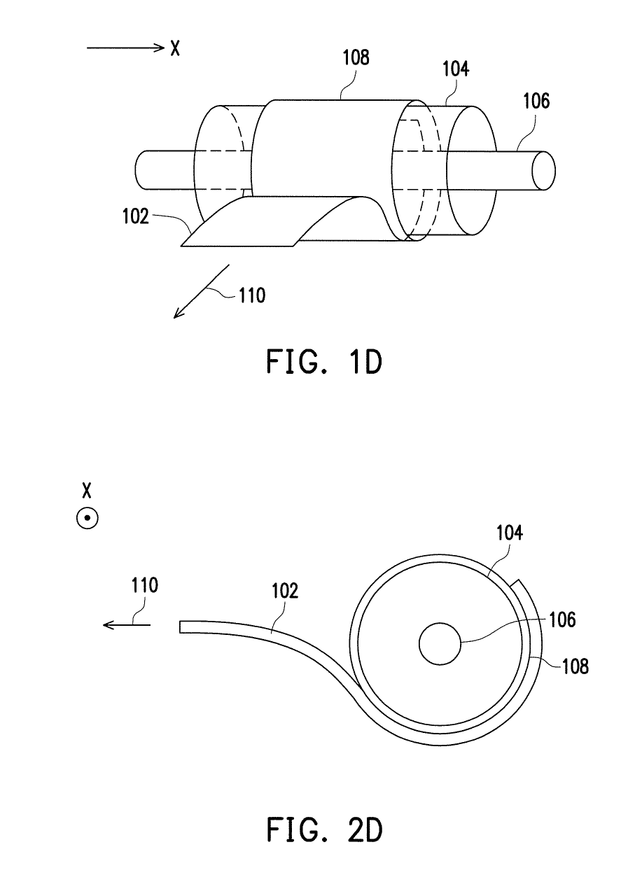

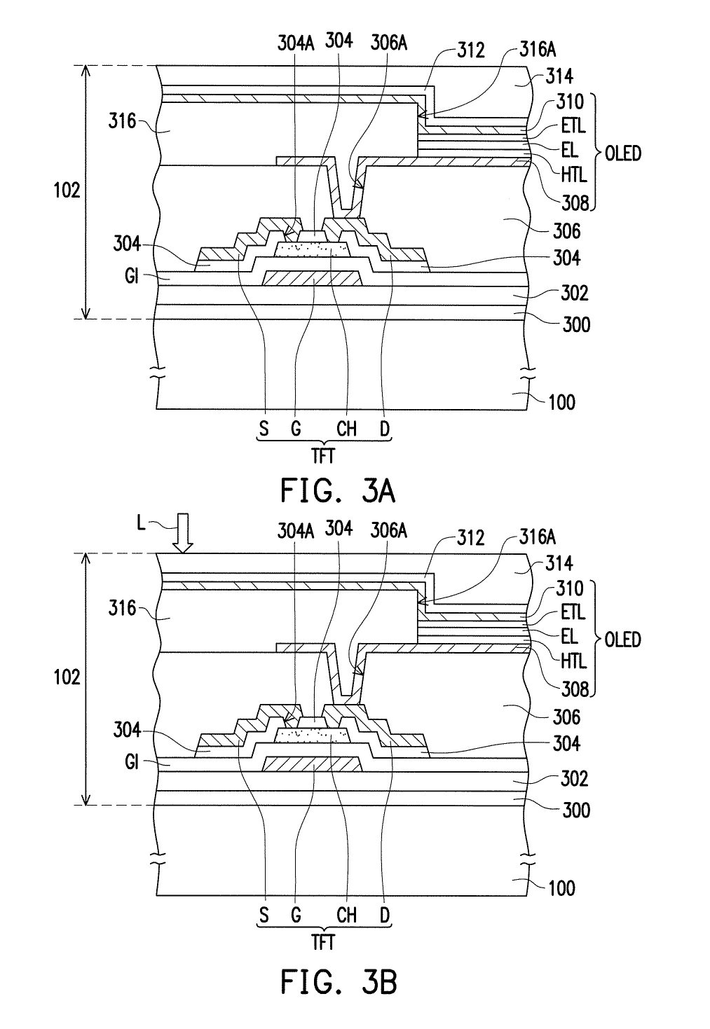

FIG. 1A to FIG. 1D are schematic flow charts of a removing method of a flexible device according to an embodiment of the invention. FIG. 2A to FIG. 2D are schematic flow charts respectively corresponding to the removing method of the flexible device of FIG. 1A to FIG. 1D shown in a direction x. FIG. 3A to FIG. 3B are schematic views of a manufacturing process of a flexible device according to an embodiment of the invention.

Referring to FIG. 3A, first, a plurality of flexible devices 102 are formed on a carrier 100. Nevertheless, in order to clearly explain the invention, only one of the flexible devices 102 is shown in FIG. 3A. The material of the carrier 100 may include but may not be limited to glass. With sufficient supports and favorable technique (e.g., temperatures, acids and bases, etc.) tolerance provided, the material of the carrier 100 may also include polymer. The flexible device 102 may be, for example, an electronic device with flexible and bendable characteristics. The electronic device may be a display panel, a touch panel, a solar cell, etc and may not be particularly limited. Examples of the display panel include an organic light-emitting diode (OLED) display panel or an electronic paper display (EPD) panel, etc. The manufacturing process of the flexible device 102 is described in the following with respect to the organic light-emitting diode (OLED) display panel.

A flexible thin film 300 is formed on the carrier 100. The forming method of the flexible thin film 300 includes but is not limited to spin coating, and other methods suitable for forming the flexible thin film 300 may also be applied to the embodiments of the invention. The flexible thin film 300 is equipped with properties of low viscosity and high glass transition temperature (Tg), such that the flexible thin film 300 is able to withstand a high temperature (e.g., 350° C. or higher) of technique used in a subsequent process. Moreover, an adhesion between the flexible thin film 300 formed and the carrier 100 may be less than and equal to 0.196 N/cm, wherein the adhesion may not change significantly when affected by subsequent technique conditions (e.g., a high temperature process of 350° C. or higher). As such, in the manufacturing process of the flexible device 102, the flexible thin film 300 may be securely attached to the carrier 100, and after the manufacturing process of the flexible device 102 is completed, the flexible device 102 may be easily peeled off from the carrier 100. In an embodiment of the invention, the material of the flexible thin film 300 includes polymer, such as polyimide with a glass transition temperature of 450° C. or other suitable materials.

Next, a first barrier film 302 is formed on the flexible thin film 300. As such, water and oxygen may be blocked after the manufacturing process of the flexible device 102 is completed. The first barrier film 302 may be formed by an inorganic material and/or an organic material stacked alternately as a multi-layered structure. The inorganic material includes but is not limited to Al₂O₃, SiNₓ, or SiOₓ. The organic material includes but is not limited to an acrylic base material or a parylene base material. The order of how the inorganic material and the organic material are stacked and the amount of the organic material and the inorganic material are not particularly limited as long as the water and oxygen blocking effect of the first barrier film 302 is maintained.

A thin-film transistor TFT is framed on the first barrier film 302, and the first barrier film 302 is thus located between the thin-film transistor TFT and the flexible thin film 300. The thin-film transistor TFT includes a gate G, a channel layer CH, a source S, and a drain D. First, the gate G is formed on the first barrier film 302. The gate G, for example, is made of a metal material, but the invention is not limited thereto. In other embodiments, the gate G may be made of other conductive materials (e.g., alloy, metal nitride, metal oxide, metal oxynitride, or a stack layer having metal and the other conductive materials). Then, a gate insulation layer GI is foinied on the gate G so as to cover the gate G and a portion of the first barrier film 302. The material of the gate insulation layer GI may include an inorganic material (e.g., silicon oxide, silicon nitride, silicon oxynitride, or a stacked layer having at least two of the aforementioned materials), an organic material, or a combination thereof. Next, after a single-layered or a multi-layered semiconductor layer (not shown) is formed on the gate insulation layer GI, the semiconductor layer is patterned, such that the channel layer CH is formed above the gate G. The material of the channel layer CH may selectively be an amorphous silicon material, a polysilicon material, or a metal oxide semiconductor, including amorphous silicon (a-Si), indium-gallium-zinc oxide (IGZO), zinc oxide (ZnO), tin oxide (SnO), indium-zinc oxide (IZO), gallium-zinc oxide (GZO), zinc-tin oxide (ZTO), indium-tin oxide (ITO), or etc. Afterwards, in order to prevent the channel layer CH from being damaged by etching solution used by the technique (e.g., the etching technique) to form the source S and the drain D subsequently, an etching stop layer 304 may be used to cover the channel layer CH before forming the source S and the drain D. The etching stop layer 304 has contact windows 304A located at two opposite sides of the channel layer CH and exposing the channel layer CH. Next, the source S and the drain D are formed on the etching stop layer 304 and the channel layer CH, wherein the source S and the drain D respectively fill the contact windows 304A located at the two opposite sides of the channel layer CH and thus are electrically connected to the channel layer CH. The source S and the drain D are generally made of a metal material; nevertheless, the invention is not limited thereto. In other embodiments, the source S and the drain D may be made of other conductive materials (e.g., alloy, metal nitride, metal oxide, metal oxynitride, or other suitable materials) or a stack layer having metal and the other conductive materials. The manufacturing process of the thin-film transistor TFT of the present embodiment is thereby completed.

Next, the thin-film transistor TFT is covered by a passivation layer 306, and a contact window 306A exposing the drain D is formed in the passivation layer 306.

An organic light-emitting diode OLED is formed on the passivation layer 306. The organic light-emitting diode OLED includes a first electrode 308, a hole transporting layer HTL, an emission layer EL, an electron transporting layer ETL, and a second electrode 310. The first electrode 308 (e.g., an anode) is formed on the passivation layer 306 and fills the contact window 306A and thus is electrically connected to the drain D. The material of the first electrode 308 may include metal, any conductive material capable of reflecting light, or any combination of the foregoing materials. A pixel definition layer 316 is formed to cover the passivation layer 306 and the first electrode 308, and an opening 316A exposing the first electrode 308 is formed in the pixel definition layer 316. The opening 316A is filled with an organic material so as to form the hole transporting layer HTL, the emission layer EL, and the electron transporting layer ETL, but the invention is not limited thereto. In some embodiments, a hole injection layer, an electron blocking layer, an electron injection layer, or a hole blocking layer may also be formed in the opening 316A as required. Next, a second electrode 310 (e.g., a cathode) is formed on the pixel definition layer 316, and the second electrode 310 fills the opening 316A so as to be electrically connected to the electron transporting layer ETL. The material of the second electrode 310 may include thin metal (silver, aluminum), indium tin oxide, indium zinc oxide, aluminum zinc oxide, any transparent conductive material, or any combination of the foregoing materials.

The organic light-emitting diode OLED is covered by a second barrier film 312 to block water vapor. The second barrier film 312 may be formed by an inorganic material and/or an organic material stacked alternately as a multi-layered structure. The inorganic material includes but is not limited to Al₂O₃, SiNₓ, or SiOₓ. The organic material includes but is not limited to an acrylic base material or a parylene base material. The order of how the inorganic material and the organic material are stacked and the amount of the organic material and the inorganic material are not particularly limited as long as the water and oxygen blocking effect of the second barrier film 312 is maintained. In addition, after the second barrier film 312 is formed, other barrier films 314 may be attached so as to enhance the water vapor blocking effect. The manufacturing process of the flexible device 102 of the present embodiment is thereby completed.

Referring to FIG. 3B, the flexible devices 102 may be cut next, so as to define portions of the flexible devices 102 required to be removed. The cutting method includes a laser L. Afterwards, the flexible devices 102 are removed from the carrier 100 through the following method.

Referring to FIG. 1A and FIG. 2A together, first, a roller 104, a non-visible light source 106, and a photosensitive tape 108 are provided. The photosensitive tape 108 on the roller 104 is then enabled to lean against one side of the flexible device 102, such that the flexible device 102 is attached to the photosensitive tape 108. A diameter of the roller 104 is not particularly limited as long as the diameter of the roller 104 is designed to ensure well functioning of the flexible device 102. The material of the roller 104 includes, for example, a material pervious to non-visible light, such that when irradiation is performed subsequently by the non-visible light source 106, the photosensitive tape 108 is irradiated by the non-visible light source 106. In other words, the roller 104 may be but may not be limited to transparent. The non-visible light source 106 is disposed in an inner portion of the roller 104, such that the photosensitive tape 108 located at an outer surface (not shown) of the roller 104 may be entirely irradiated by the non-visible light source 106. In the present embodiment, the non-visible light source 106 of a tubular shape is disposed at but is not limited to an axle center of the roller 104, for example. In other embodiments, the non-visible light source 106 may be shaped as other suitable shapes and be disposed at the inner portion of the roller 104. An intensity of the non-visible light source 106 may range between 800 mJ/cm² plus or minus 10%. For instance, the non-visible light source 106 may be an ultraviolet light source with a wavelength of, for example, 365 nm. The photosensitive tape 108 winds around the roller 104 and is fixed on the outer surface (not shown) of the roller 104, wherein a width of the photosensitive tape 108 may be equal to a length of the roller 104, or the width of the photosensitive tape 108 may be adjusted according to a size of the flexible device 102. The material of the photosensitive tape 108 may be, for example, a material sensitive to non-visible light which enables an adhesion between the photosensitive tape 108 and the flexible device 102 to be weakened after being irradiated by non-visible light. Specifically, before being irradiated by non-visible light, the adhesion (e.g., greater than 1 N/cm) between the photosensitive tape 108 and the flexible device 102 may be greater than an adhesion (e.g., less than and equal to 0.196 N/cm) between the carrier 100 and the flexible device 102, such that the flexible device 102 may be peeled off from the carrier 100. The adhesion between the photosensitive tape 108 and the flexible device 102 may be less than 0.1 N/cm after being irradiated by non-visible light, such that the flexible device 102 may be easily removed from the photosensitive tape 108.

Referring to FIG. 1B and FIG. 2B together, the flexible device 102 is peeled off from the carrier 100 through the photosensitive tape 108. Specifically, the carrier 100 (along with the flexible device 102) are moved in a machine direction MD, and the roller 104 is rotated in a circumferential direction CD with the axle center being fixed; thereby, the flexible device 102 is adhered by the photosensitive tape 108 and is wound around the roller 104. Nevertheless, the invention is not limited thereto, and other methods in which the flexible device 102 is enabled to be wound around the photosensitive tape 108 of the roller 104 may also be applicable to the invention.

Referring to FIG. 1C and FIG. 2C together, after the flexible device 102 is entirely peeled off from the carrier 100, the non-visible light source 106 is used to irradiate the photosensitive tape 108 so as to weaken the adhesion between the photosensitive tape 108 and the flexible device 102, wherein an energy of the non-sensitive light source 106 is less than that of laser, such that the problem in which damages are made to the flexible device 102 owning to use of high energy laser in the prior art is thus prevented. Moreover, use of the non-visible light source also requires less cost. In an embodiment of the invention, a distance between the non-visible light source 106 and the flexible device 102 may be 100 mm.

Referring to FIG. 1D and FIG. 2D together, one side of the flexible device 102 is served as an initial position, and the flexible device 102 is removed from the photosensitive tape 108 irradiated by non-visible light in a direction 110 away from the roller 104. The removing method of the flexible device 102 of the present embodiment is thereby completed.

In view of the foregoing, according to the removing method of the flexible device provided by the embodiments of the invention, after the flexible device is peeled off from the carrier by the roller with the photosensitive tape fixed onto the outer surface, as the adhesion between the photosensitive tape and the flexible device is weakened by the non-visible light source, damages caused by laser on the flexible device found in the prior art is therefore prevented, and equipment costs and supply costs are effectively lowered as well.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A removing method of a flexible device, the flexible device being fonned on a carrier, the removing method of the flexible device comprising:
providing a roller, a non-visible light source, and a photosensitive tape, the non-visible light source being disposed at an axle center of the roller, the photosensitive tape being fixed on an outer surface of the roller;
positioning the photosensitive tape on the roller to lean against the flexible device and rotating the roller to rotate so as to peel the flexible device off the carrier;
irradiating the photosensitive tape with the non-visible light source; and
removing the flexible device from the photosensitive tape.

2. The removing method of the flexible device as claimed in claim 1, further comprising cutting the flexible device before performing the removing method of the flexible device.

3. The removing method of the flexible device as claimed in claim 2, wherein the method of cutting the flexible device comprises a laser.

4. The removing method of the flexible device as claimed in claim 1, wherein an adhesion between the carrier and the flexible device is less than and equal to 0.196 N/cm.

5. The removing method of the flexible device as claimed in claim 1, wherein an adhesion between the photosensitive tape and the flexible device is greater than 1 N/cm before performing the irradiation.

6. The removing method of the flexible device as claimed in claim 1, wherein an adhesion between the photosensitive tape and the flexible device is less than 0.1 N/cm after performing the irradiation.

7. The removing method of the flexible device as claimed in claim 1, wherein the roller is a material pervious to non-visible light.

8. The removing method of the flexible device as claimed in claim 1, wherein an intensity of the non-visible light source ranges between 800 mJ/cm2 plus or minus 10%.

9. The removing method of the flexible device as claimed in claim 1, wherein a distance between the non-visible light source and the flexible device is 100 mm.

10. The removing method of the flexible device as claimed in claim 1, wherein the non-visible light source comprises an ultraviolet light source.
